(19) United States
(12) Patent Application Publication
(10) Pub. No.: US 2010/0165733 A1
(43) Pub. Date: Jul. 1, 2010

(54) NAND NONVOLATILE SEMICONDUCTOR MEMORY

(76) Inventors: Dai NAKAMURA, Kawasaki-shi (JP); Koichi FUKUDA, Yokohama-shi (JP); Yoshihisa WATANABE, Yokohama-shi (JP); Makoto IWAI, Chigasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/646,551

(22) Filed: Dec. 23, 2009

(30) Foreign Application Priority Data
Dec. 26, 2008 (JP) 2008-334883

(51) Int. Cl. G11C 16/04; G11C 16/06

(52) U.S. Cl. 365/185.17; 365/185.23

(57) ABSTRACT

A NAND nonvolatile semiconductor memory includes a plurality of series-connected memory cells each includes a charge storage layer and control gate electrode, a plurality of word lines respectively connected to control gate electrodes of the memory cells, a first selection transistor connected between one end of the memory cells and a source line, a second selection transistor connected between the other end of the memory cells and a bit line, and a driver configured to control voltages applied to the word lines. The driver applies a first voltage to a first word line connected to a selected memory cell, and applies a cutoff voltage that cuts off a channel of a memory cell to second word lines of a number not less than three arranged side by side on the source line side with respect to the first word line during a write operation.

### CROSS-REFERENCE TO RELATED APPLICATIONS

This application is based upon and claims the benefit of priority from prior Japanese Patent Application No. 2008-334883, filed Dec. 26, 2008, the entire contents of which are incorporated herein by reference.

### BACKGROUND OF THE INVENTION

1. Field of the Invention

This invention relates to the write operation of a NAND nonvolatile semiconductor memory.

2. Description of the Related Art

As one example of a NAND nonvolatile semiconductor memory, a NAND flash memory is known.

If a write voltage is applied to a word line (selected word line) connected to a selected memory cell to which data is to be written in the write operation of the NAND flash memory, the write voltage is also applied to a memory cell (write inhibition memory cell) that is connected to the selected word line and to which no data is to be written. Therefore, it is necessary to prevent data from being written to the write inhibition memory cell.

As a method for performing the control operation to prevent data from being written to the write inhibition memory cell, a self-boost (SB) method and local self-boost (LSB) method (for example, Jpn. Pat. Appln. KOKAI Publication No. 2008-47278, Jpn. Pat. Appln. KOKAI Publication No. 2007-42165 and Jpn. Pat. Appln. KOKAI Publication No. 2000-48581) are known.

The self-boost method makes a NAND string including a write inhibition memory cell float and applies a pass voltage to respective word lines. Since the channel voltage in the NAND string is boosted because of capacitive coupling, the strength of an electric field applied to the gate insulating film of the selected memory cell is reduced. Therefore, injection of electrons into the charge storage layer of the write inhibition memory cell is limited.

The local self-boost method is different from the self-boost method in that a cutoff voltage that cuts off the channel of a memory cell is applied to a word line that is separated from a non-selected memory cell with plural word lines disposed therebetween on the source line side and is similar to the self-boost method in other respects. In this method, since it is sufficient to partially boost voltages of only the channel regions of the memory cells lying on the bit line side with respect to the cutoff memory cell, the boosting efficiency is enhanced.

### BRIEF SUMMARY OF THE INVENTION

According to an aspect of the present invention, there is provided a NAND nonvolatile semiconductor memory comprising: a plurality of series-connected memory cells each comprising a charge storage layer and control gate electrode, a plurality of word lines respectively connected to control gate electrodes of the memory cells, a first selection transistor connected between one end of the memory cells and a source line, a second selection transistor connected between the other end of the memory cells and a bit line, and a driver configured to control voltages applied to the word lines, wherein the driver applies a first voltage to a first word line connected to a selected memory cell, and applies a cutoff voltage that cuts off a channel of a memory cell to second word lines of a number not less than three arranged side by side on the source line side with respect to the first word line during a write operation.

According to an aspect of the present invention, there is provided a NAND nonvolatile semiconductor memory comprising: a plurality of series-connected memory cells each comprising a charge storage layer and control gate electrode, a plurality of word lines respectively connected to control gate electrodes of the memory cells, a first selection transistor connected between one end of the memory cells and a source line, a second selection transistor connected between the other end of the memory cells and a bit line, and a driver configured to control voltages applied to the plurality of word lines, wherein the driver applies a first voltage to a first word line connected to a selected memory cell, makes a second word line arranged on the source line side of the first word line float, applies a second voltage lower than the first voltage to a third word line adjacent to the second word line on the source line side, and applies a cutoff voltage that cuts off a channel of a memory cell to a fourth word line adjacent to the third word line on the source line side during a write operation.

According to an aspect of the present invention, there is provided a NAND nonvolatile semiconductor memory comprising: a plurality of series-connected memory cells each comprising a charge storage layer and control gate electrode, a plurality of word lines respectively connected to control gate electrodes of the memory cells, a first selection transistor connected between one end of the memory cells and a source line, a second selection transistor connected between the other end of the memory cells and a bit line, and a driver configured to control voltages applied to the plurality of word lines, wherein the driver applies a second voltage lower than a first voltage to a second word line arranged on the source line side of a first word line connected to a selected memory cell, and applies a cutoff voltage that cuts off a channel of a memory cell to a third word line adjacent to the second word line on the source line side after applying the first voltage to the first word line during a write operation.

### BRIEF DESCRIPTION OF THE SEVERAL VIEWS OF THE DRAWING

FIG. 1 is a block diagram showing a NAND nonvolatile semiconductor memory.

FIG. 2 is a diagram showing a circuit example of a memory cell array and word line driver.

FIG. 3 is a plan view of a NAND cell unit.

FIG. 4 is a cross-sectional view of the NAND cell unit.

FIG. 5 is a diagram showing the voltage relationship during a write operation.

FIG. 6 is a diagram showing a timing chart of application of voltages to word lines during the write operation.

FIG. 7 is a view showing the magnitudes of channel voltages during the write operation.

FIG. 8 is a diagram showing the voltage relationship during the write operation.

FIG. 9 is a diagram showing the voltage relationship during the write operation.

FIG. 10 is a diagram showing a timing chart of application of voltages to word lines during the write operation.

FIG. 11 is a view showing the magnitudes of channel voltages during the write operation.

FIG. 12 is a diagram showing the voltage relationship during the write operation.

FIG. 13 is a diagram showing the voltage relationship during the write operation.

FIG. 14 is a diagram showing a timing chart of application of voltages to word lines during the write operation.

FIG. 15 is a diagram showing the voltage relationship during the write operation.

FIG. 16 is a diagram showing a timing chart of application of voltages to word lines during the write operation.

FIG. 17 is a view showing the magnitudes of channel voltages during the write operation.

FIG. 18 is a diagram showing the voltage relationship during the write operation.

FIG. 19 is a view showing a system as an application example.

### DETAILED DESCRIPTION OF THE INVENTION

The embodiments of the present invention will be described hereinafter with reference to the accompanying drawings. In the description which follows, the same or functionally equivalent elements are denoted by the same reference numerals, to thereby simplify the description.

### 1. Outline

In an example of this invention, the rise rate in the cutoff voltage due to coupling with a word line to which a pass voltage is applied is lowered and the recovery time is reduced by use of the following three methods.

The first method is a method in which the number of word lines to which the cutoff voltage is applied is set to three or more. In this method, the cutoff voltage is applied to the word lines adjacent to a central one of the word lines to which the cutoff voltage is applied. Therefore, it is difficult to be influenced by the coupling with the pass voltage and a voltage rise due to the pass voltage can be alleviated.

The second method is a method in which the word line between the word line whose voltage is the pass voltage and the word line whose voltage is the intermediate voltage is made to float. In this method, the effect that the intermediate voltage is boosted because of coupling with the pass voltage is alleviated by locating the floating word line. Therefore, a voltage rise in the cutoff voltage can be alleviated.

The third method is a method for performing the control operation to apply a cutoff voltage and intermediate voltage with a preset time delay from timing at which the pass voltage is applied. In this method, the rise in the intermediate voltage and cutoff voltage due to coupling with the pass voltage can be alleviated in comparison with a case wherein the intermediate voltage and cutoff voltage are applied at the same timing as application of the pass voltage.

In the above three methods, the recovery time can be reduced and the channel of the memory cell can be cut off without fail. Therefore, the time required for boosting the voltages of the channel regions can be reduced and the write time can be reduced.

### 2. Embodiment

### (1) NAND Nonvolatile Semiconductor Memory

First, the outline of a NAND nonvolatile semiconductor memory is explained.

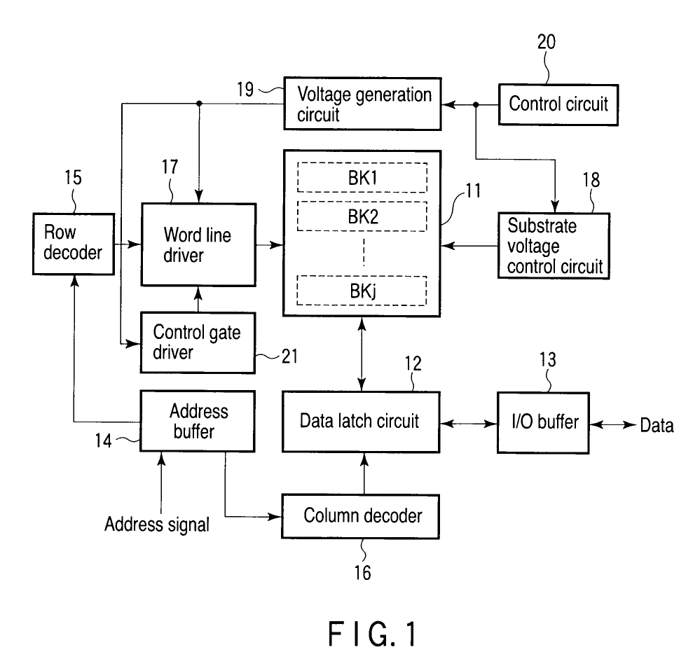

FIG. 1 is a diagram showing the whole portion of the NAND nonvolatile semiconductor memory.

A memory cell array 11 comprises a plurality of blocks BK1, BK2, . . . , BKj. Each of blocks BK1, BK2, . . . , BKj comprises a plurality of NAND cell units.

A data latch circuit 12 has a function of temporarily latching data at the read/program time and is configured by a flip-flop circuit, for example. An input/output (I/O) buffer 13 functions as a data interface circuit and an address buffer 14 functions as an interface circuit for an address signal. In the address signal, a block address signal, row address signal and column address signal are contained.

A row decoder 15 selects one of blocks BK1, BK2, . . . , BKj according to the block address signal and selects one of a plurality of word lines in the selected block according to the row address signal. A word line driver 17 drives a plurality of word lines in the selected block.

A column decoder 16 selects one of a plurality of bit lines according to the column address signal.

A substrate voltage control circuit 18 controls the voltage of a semiconductor substrate on which memory cells are formed. It is assumed that the semiconductor substrate may contain a well in the semiconductor substrate.

A voltage generation circuit 19 generates a voltage supplied to the plurality of word lines in the selected block. In this embodiment, the voltage generation circuit 19 generates write voltage Vpgm, pass voltage Vpass, intermediate voltage Vgp and cutoff voltage Viso during a write operation.

A control circuit 20 controls the operations of the substrate voltage control circuit 18 and voltage generation circuit 19.

A control gate driver 21 selects values of voltages supplied to the word lines in the selected block based on information such as the operation mode, the position of the selected word line and the like.

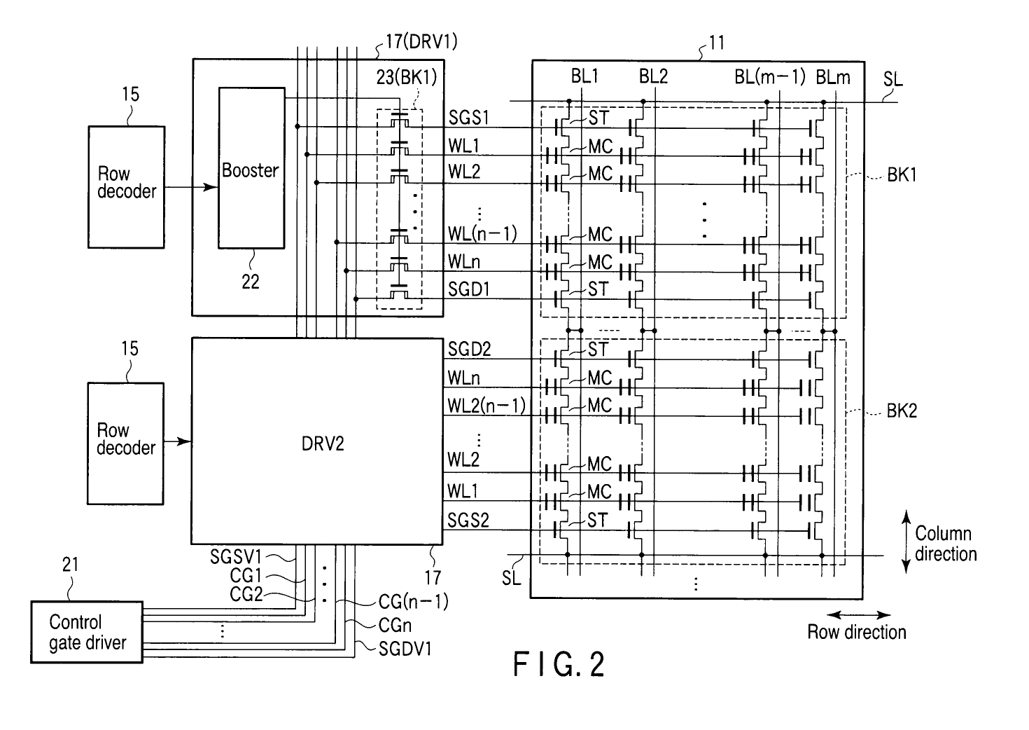

FIG. 2 shows a circuit example of the memory cell array and word line driver.

The memory cell array 11 comprises a plurality of blocks BK1, BK2, . . . arranged in a column direction. Each of blocks BK1, BK2, . . . comprises a plurality of NAND cell units arranged in a row direction. Each NAND cell unit comprises a NAND string configured by a plurality of series-connected memory cells MC and two select gate transistors ST connected to both ends thereof.

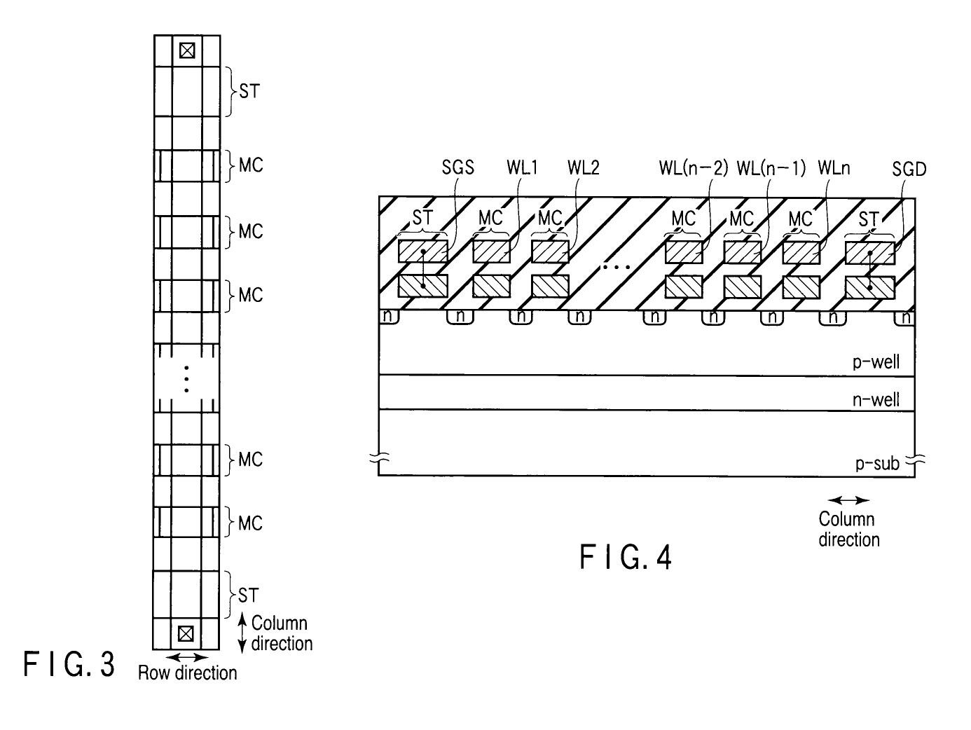

For example, the NAND cell unit has a layout as shown in FIG. 3. The cross-sectional structure of the NAND cell unit in the column direction becomes the structure as shown in FIG. 4, for example.

One-side ends of the plurality of NAND cell units are respectively connected to bit lines BL1, BL2, . . . , BLm and the other ends thereof are commonly connected to a source line SL.

A plurality of word lines WL1, . . . , WLn, . . . , a plurality of select gate lines SGS1, SGS2, . . . and a plurality of select gate lines SGD1, SGD2, . . . are arranged on the memory cell array 11.

For example, in block BK1, n (n is a plural number) word lines WL1, . . . , WLn and two select gate lines SGS1, SGD1 are arranged. Word lines WL1, . . . , WLn and select gate lines SGS1, SGD1 are arranged to extend in the row direction and respectively connected to signal lines (control gate lines) CG1, . . . , CGn and signal lines SGSV1, SGDV1 via a transfer transistor unit 23 (BK1) in the word line driver 17 (DRV1).

The signal lines CG1, . . . , CGn, SGSV1 and SGDV1 extend in a column direction that intersects with the row direction and connected to the control gate driver 21.

The transfer transistor unit 23 (BK1) comprises high-voltage metal insulator semiconductor field-effect transistors (MISFETs) to transfer voltages higher than the power source voltage.

A booster 22 in the word line driver 17 (DRV1) receives a decode signal output from the row decoder 15. The booster 22 turns on the transfer transistor unit 23 (BK1) when block BK1 is selected and turns off the transfer transistor unit 23 (BK1) when block BK1 is not selected.

### (2) First Embodiment

As an example of the first embodiment, a case wherein the number of word lines to which the cutoff voltage is applied is set to three is explained.

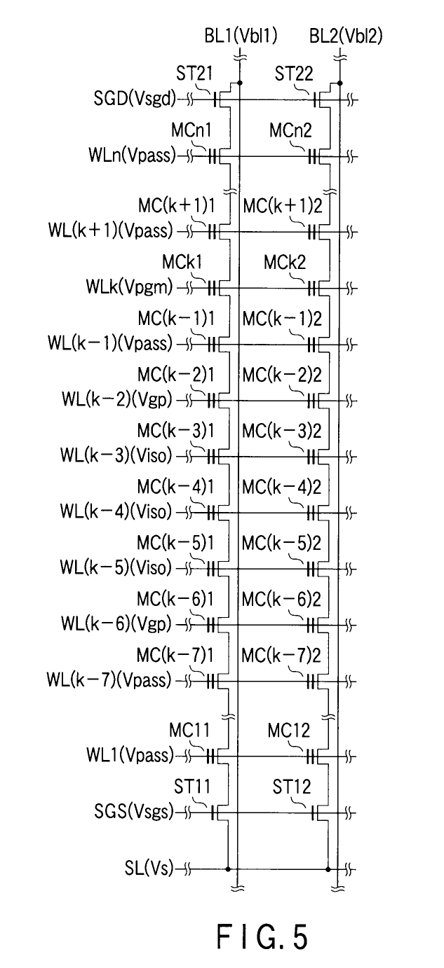

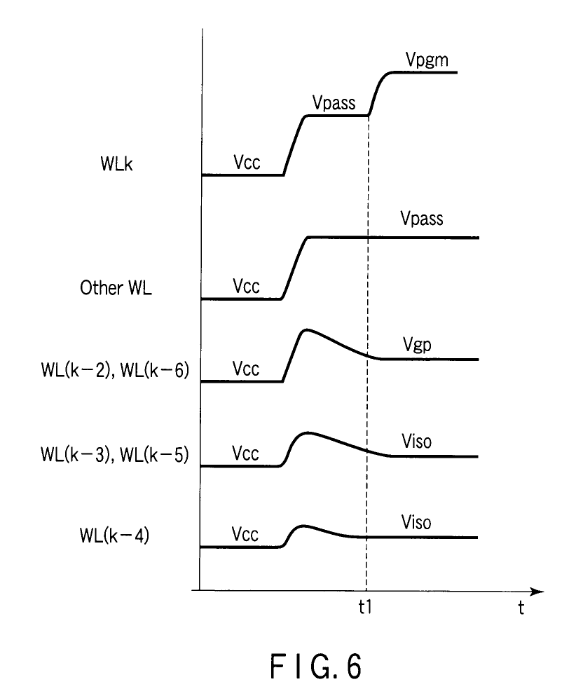

FIG. 5 shows the voltage relationship in the NAND cell unit during the write operation and FIG. 6 shows a timing chart of voltages applied to word lines during the write operation.

First, a method for applying voltages to the word lines during the write operation when the central word line WLk (k is an integer greater than 6) in the NAND string is used as a selected word line is explained with reference to FIGS. 5 and 6. In this case, it is supposed that memory cell MCk1 is a selected memory cell and memory cell MCk2 is a write inhibition memory cell.

First, voltages Vb11, Vb12 are respectively applied to bit lines BL1, BL2. For example, it is supposed that voltage Vb11 is zero and voltage Vb12 is 2.5 V. Further, positive source voltage Vs (for example, a voltage of 2.5 V or less) is applied to the source line SL.

Voltage Vsgd (for example, a voltage of 2.5 V or less) is applied to selection gate line SGD of bit line selection gate transistors ST21, ST22. Voltage Vsgs (for example, 0 V) is applied to selection gate line SGS of source-side selection gate transistors ST11, ST12. Thus, selection gate transistors ST11, ST12 are cut off.

In the NAND cell unit including no selected memory cell, the channel region in the NAND string is charged to voltage Vcc (for example, approximately 0.5 V) via the selection gate transistor and then made to float. In this case, Vcc is expressed by Vcc=Vb12−Vtsg and Vtsg is the threshold voltage of the selection gate transistor and is approximately 2.0 V, for example.

After this, cutoff voltage Viso (for example, approximately 1.0 V) is applied to word lines WL(k−3), WL(k−4) and WL(k−5), intermediate voltage Vgp (for example, not lower than 1.0 V and lower than 10 V) is applied to word lines WL(k−2) and WL(k−6), and pass voltage Vpass (for example, approximately 10 V) is applied to the other word lines. Pass voltage Vpass is used to turn on the non-selected memory cells irrespective of holding data. Intermediate voltage Vgp is used to prevent erroneous writing to a second memory cell adjacent to a first memory cell to which the cutoff voltage is applied because of gate induced drain leakage (GIDL) and is set lower than pass voltage Vpass.

Then, after the channel voltage in the NAND string containing the write inhibition memory cell is sufficiently boosted (when the time t1 has elapsed), write voltage Vpgm (for example, 20 V) is applied to selected word line WLk.

As shown in FIG. 6, the voltage applied to the word line will be boosted because of coupling between the adjacent word lines when pass voltage Vpass is applied. Therefore, intermediate voltage Vgp applied to word line WL(k−2) is boosted because of coupling with pass voltage Vpass applied to word line WL(k−1). Further, cutoff voltage Viso applied to word line WL(k−3) is boosted because of coupling with boosted intermediate voltage Vgp applied to word line WL(k−2).

However, in the first embodiment, the number of word lines to which cutoff voltage Viso is applied is set to three. Therefore, cutoff voltage Viso applied to word line WL(k−4) is boosted because of coupling with boosted cutoff voltage Viso. As a result, the boosting amount of cutoff voltage Viso applied to word line WL(k−4) is reduced in comparison with a case wherein cutoff voltage Viso is applied to only one word line.

Therefore, the recovery time required for returning boosted cutoff voltage Viso of word line WL(k−4) to the original voltage becomes shorter and the memory cell is cut off without fail.

In the example of FIG. 5, a case wherein the number of word lines to which pass voltage Vpass is applied and that are arranged between selected word line WLk and word line WL(k−2) to which intermediate voltage Vgp is applied is set to one is shown. However, this invention is not limited to this case and the number of word lines may be set to a plural number.

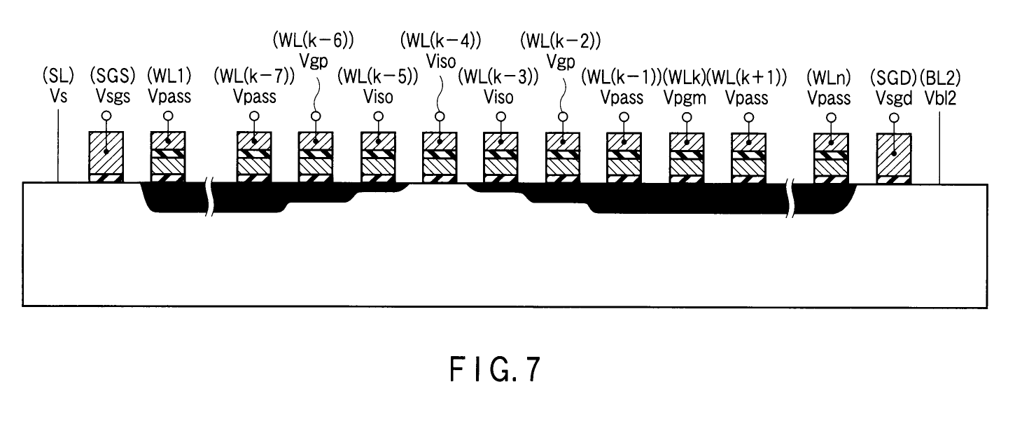

FIG. 7 is a cross-sectional view of the cell unit in the column direction. The depth of a region of the channel region painted in black indicates the magnitude of the channel voltage when pass voltage Vpass is applied to the word line.

Even when cutoff voltage Viso applied to word line WL(k−3) is boosted because of coupling with intermediate voltage Vgp and the channel of the memory cell cannot be cut off, the channel of the memory cell can be cut off without fail by use of the cutoff voltage applied to word line WL(k−4). Therefore, the voltage of the channel region of the memory cell is efficiently boosted. As a result, the timing at which intermediate voltage Vgp is applied to the selected memory cell can be made earlier, and therefore, the time required for the write operation can be reduced.

Next, a case wherein word line WLk for which k≦6 is selected is explained. In the case of selected word line WLk for which k≦6, no memory cell to be cut off is present on the source line side of selected word line WLk in some cases. Therefore, the voltage of the channel region of the memory cell is boosted by use of the self-boost method.

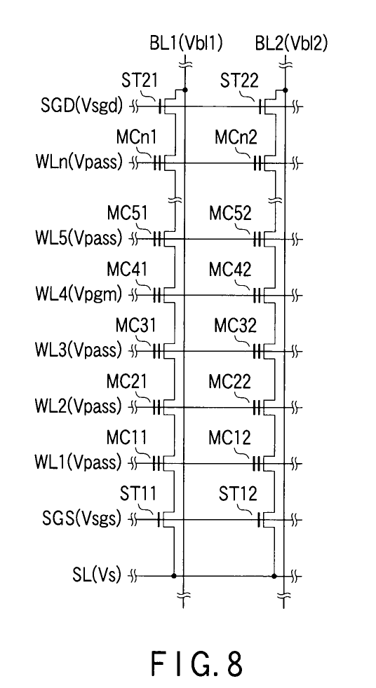

FIG. 8 shows a case wherein word line WL4 is selected. First, as in the embodiment in which word line WLk for which k≧7 is selected, the channel region of the NAND string including the write inhibition memory cell is made to float and pass voltage Vpass is applied to the respective word lines. The channel voltage in the NAND string is boosted because of capacitive coupling. Then, write voltage Vpgm is applied to selected word line WL4 and data is written.

In the above explanation, a case wherein the self-boost method is performed in the case of selected word line WLk for which k≦6 is explained. However, if word line WL5 is selected, the control operation may be performed to apply cutoff voltage Viso to word lines WL1 and WL2, apply intermediate voltage Vgp to word line WL3 and apply pass voltage Vpass to the other word lines.

Further, if word line WL6 is selected, the control operation may be performed to apply cutoff voltage Viso to word lines WL1, WL2 and WL3, apply intermediate voltage Vgp to word line WL4 and apply pass voltage Vpass to the other word lines.

In the first embodiment, a case wherein the number of word lines to which the cutoff voltage is applied is set to three is explained, but the number of word lines to which the cutoff voltage is applied may be set to a desired number if it is larger than or equal to three.

As described above in detail, in the first embodiment, in order to suppress the influence caused by coupling with the pass voltage, the cutoff voltage is applied to three word lines. The central word line among the three word lines is boosted because of coupling with the cutoff voltage. Therefore, the cutoff voltage applied to the central word line is not almost boosted.

Therefore, the recovery time required for returning the boosted cutoff voltage of the word line to the original voltage becomes shorter and the memory cell is cut off without fail. Thus, the time required for boosting the voltage of the channel region is reduced and the write time is reduced.

Further, intermediate voltage Vgp lower than pass voltage Vpass is applied to the second memory cell adjacent to the first memory cell to which the cutoff voltage is applied. As a result, erroneous writing to the second memory cell can be prevented.

### (3) Second Embodiment

In the second embodiment, a word line adjacent to a word line to which the intermediate voltage is applied is made to float.

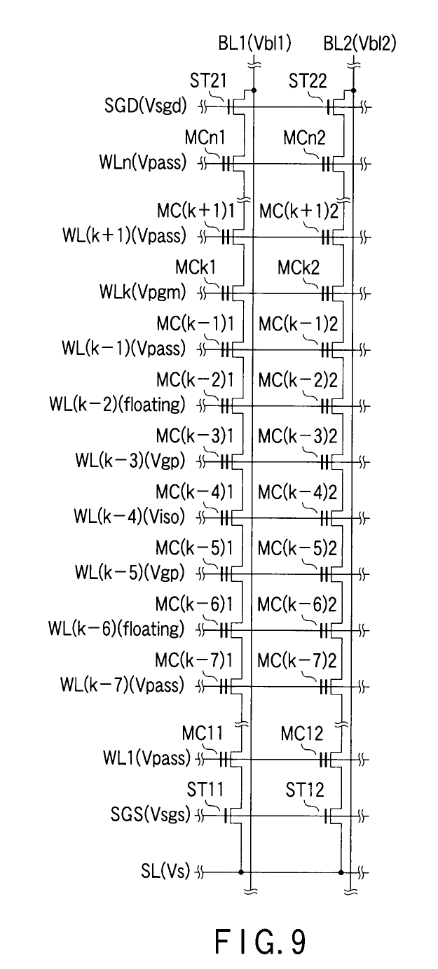

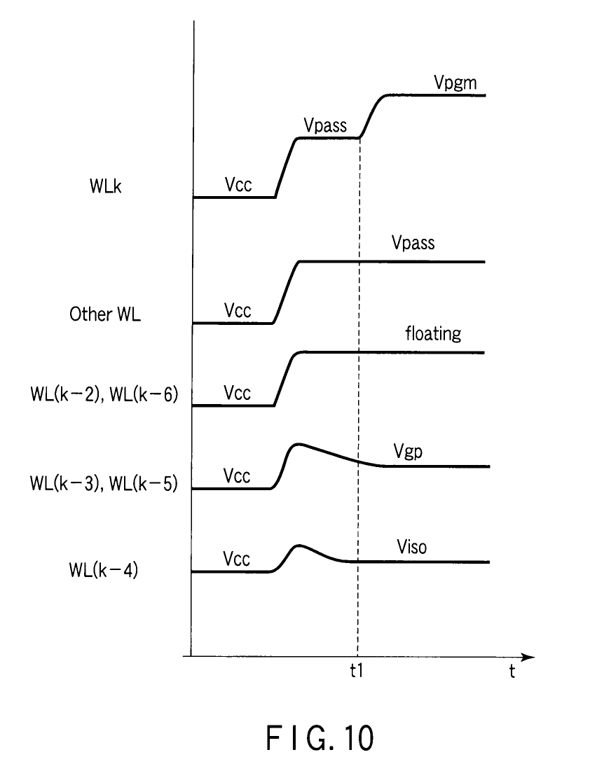

FIG. 9 shows the voltage relationship in the NAND cell unit during the write operation and FIG. 10 is a timing chart of voltages applied to word lines during the write operation.

First, a method for applying voltages to the word lines during the write operation when the central word line WLk (k is an integer greater than 6) in the NAND string is used as a selected word line is explained with reference to FIGS. 9 and 10. In this case, it is supposed that memory cell MCk1 is a selected memory cell and memory cell MCk2 is a write inhibition memory cell.

First, voltages Vb11, Vb12 are respectively applied to bit lines BL1, BL2. For example, it is supposed that voltage Vb11 is zero and voltage Vb12 is 2.5 V. Further, positive source voltage Vs (for example, a voltage of 2.5 V or less) is applied to the source line SL.

Voltage Vsgd (for example, a voltage of 2.5 V or less) is applied to selection gate line SGD of bit line selection gate transistors ST21, ST22. Voltage Vsgs (for example, 0 V) is applied to selection gate line SGS of source-side selection gate transistors ST11, ST12. Thus, selection gate transistors ST11, ST12 are cut off.

In the NAND cell unit including no selected memory cell, the channel region in the NAND string is charged to voltage Vcc (for example, approximately 0.5 V) via the selection gate transistor and is then made to float. In this case, Vcc is expressed by Vcc=Vb12−Vtsg and Vtsg is the threshold voltage of the selection gate transistor and is approximately 2.0 V, for example.

After this, cutoff voltage Viso (for example, approximately 1.0 V) is applied to word line WL(k−4), intermediate voltage Vgp (for example, not lower than 1.0 V and lower than 10 V) is applied to word lines WL(k−3) and WL(k−5), word lines WL(k−2) and WL(k−6) are made to float and pass voltage Vpass (for example, approximately 10 V) is applied to the other word lines.

At this time, in the control gate driver 21 shown in FIG. 2, the control operation is performed to isolate the control gate lines connected to the word lines that are required to be made to float from all of the voltages and thus the word lines are made to float.

Then, after the channel voltage of the NAND string containing the write inhibition memory cell is sufficiently boosted, write voltage Vpgm (for example, 20 V) is applied to selected word line WLk.

As shown in FIG. 10, the voltage applied to the word line is boosted because of coupling between the adjacent word lines when pass voltage Vpass is applied. Therefore, when pass voltage Vpass is applied, the voltages of floating word lines WL(k−2) and WL(k−6) are boosted because of coupling with pass voltage Vpass. Further, intermediate voltages Vgp applied to word lines WL(k−3) and WL(k−5) are boosted because of coupling with the floating word lines.

However, since the voltage of the floating word line does not rise to pass voltage Vpass, the boosting amount of intermediate voltage Vgp becomes smaller in comparison with the boosting amount caused by the coupling with the pass voltage. Therefore, the boosting amount in cutoff voltage Viso applied to word line WL(k−4) due to coupling with intermediate voltage Vgp is also reduced. As a result, the recovery time becomes shorter and the memory cell is cut off without fail.

In the example of FIG. 9, a case wherein the number of word lines that are arranged between selected word line WLk and floating word line WL(k−2) to which pass voltage Vpass is applied is set to one is shown. However, this invention is not limited to this case and the number of word lines may be set to a plural number.

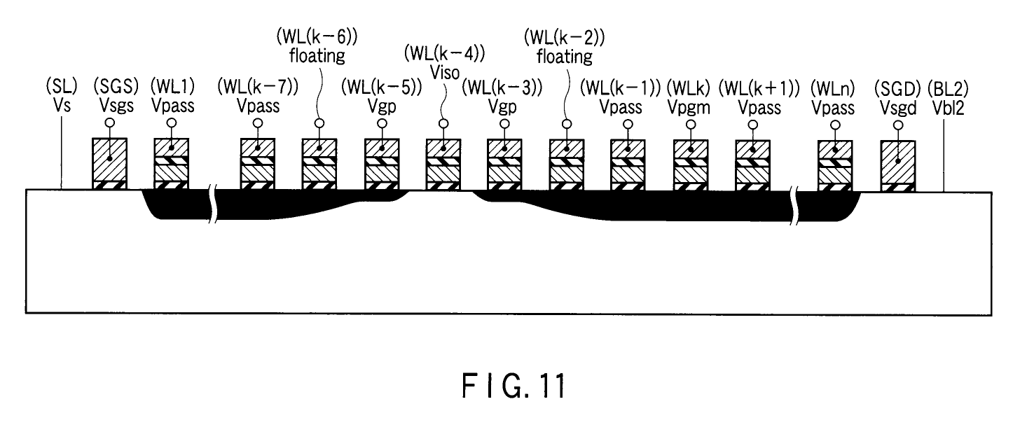

FIG. 11 is a cross-sectional view of the cell unit in the column direction. The depth of a region of the channel region painted in black indicates the magnitude of the channel voltage when pass voltage Vpass is applied to the word line.

The intermediate voltage is prevented from being directly influenced because of the coupling with the pass voltage and the boosting amount thereof is reduced by arranging the floating word line between the word line to which the pass voltage is applied and the word line to which the intermediate voltage is applied.

As a result, since the boosting amount in the cutoff voltage is reduced, the recovery time required for restoring the original cutoff voltage is reduced and the channel of the memory cell can be cut off without fail. Therefore, the voltage of the channel region of the memory cell can be efficiently boosted. As a result, the timing at which write voltage Vpgm is applied to the selected memory cell can be made earlier and the time required for the write operation can be reduced.

Next, a case wherein word line WLk for which k≦6 is selected is explained. In the case of selected word line WLk for which k≦6, no memory cell to be cut off is present on the source line side of the selected word line in some cases. Therefore, the voltage of the channel region of the memory cell is boosted by use of the self-boost method.

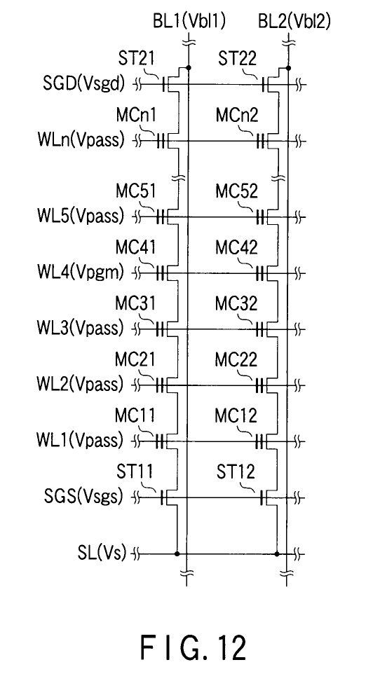

FIG. 12 shows a case wherein word line WL4 is selected. First, as in the embodiment in which word line WLk for which k≦7 is selected, the channel region of the NAND string including the write inhibition memory cell is made to float and pass voltage Vpass is applied to the respective word lines. The channel voltage in the NAND string is boosted because of capacitive coupling. Then, write voltage Vpgm is applied to selected word line WL4 and data is written.

In the above explanation, a case wherein the self-boost method is performed in the case of selected word line WLk for which k≦6 is explained. However, if word line WL5 is selected, the control operation may be performed to apply the cutoff voltage to word lines WL1 and WL3, apply intermediate voltage Vgp to word line WL2, make word line WL3 float and apply pass voltage Vpass to the other word lines.

Further, if word line WL6 is selected, the control operation may be performed to apply the intermediate voltage to word lines WL1 and WL3, apply cutoff voltage Viso to word line WL2, make word line WL4 float and apply pass voltage Vpass to the other word lines.

As described above in detail, in the second embodiment, in order to alleviate the influence caused by coupling with the pass voltage, the word line arranged between the word line to which the pass voltage is applied and the word line to which the intermediate voltage is applied is made to float. The boosting amount of the intermediate voltage is reduced by passing the intermediate voltage through the floating word line in comparison with a case wherein the intermediate voltage is directly coupled with the pass voltage and boosted. Therefore, the boosting amount in the cutoff voltage is also reduced.

Therefore, the recovery time required for returning the boosted cutoff voltage of the word line to the original voltage becomes shorter and the memory cell is cut off without fail. Thus, the time required for boosting the voltage of the channel region is reduced and the write time is reduced.

Further, intermediate voltage Vgp lower than pass voltage Vpass is applied to the second memory cell adjacent to the first memory cell to which the cutoff voltage is applied. As a result, erroneous writing to the second memory cell can be prevented.

### (4) Modification of Second Embodiment

In the modification of the second embodiment, the pass voltage is applied to the floating word line in the second embodiment with a time delay.

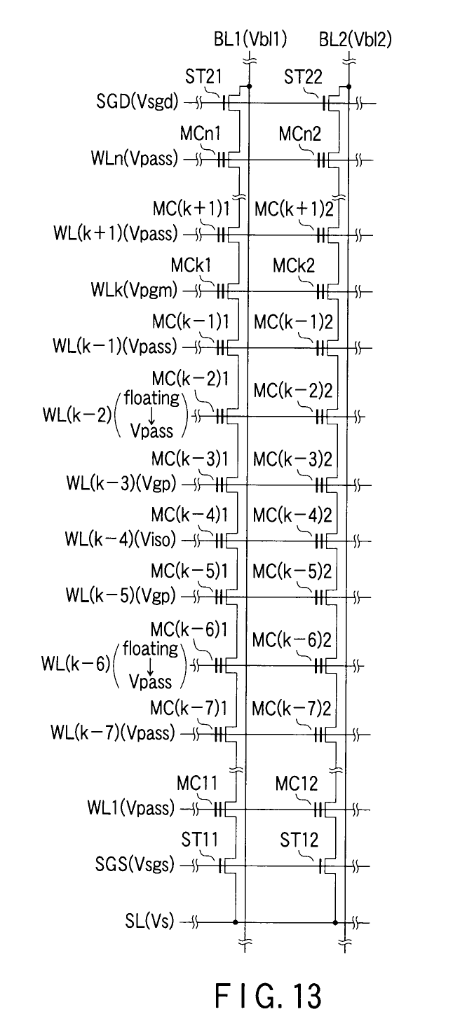

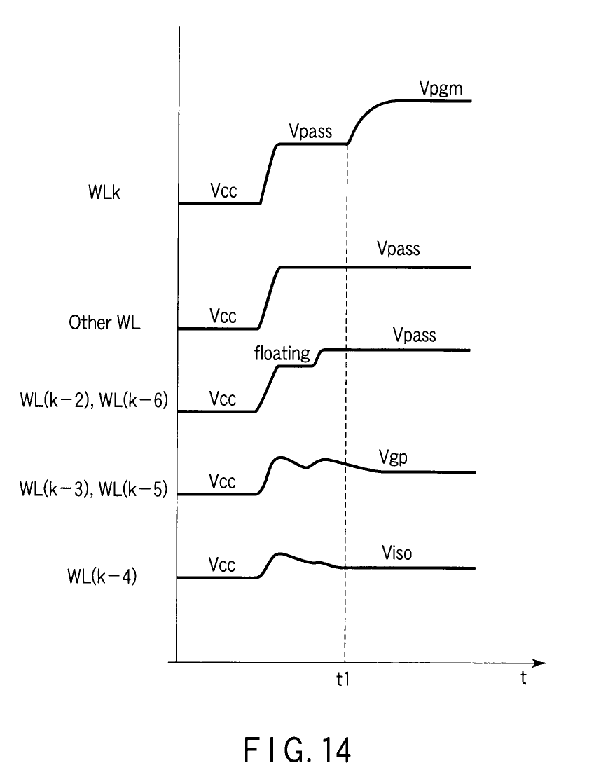

FIG. 13 shows the voltage relationship in the NAND cell unit during the write operation and FIG. 14 is a timing chart of voltages applied to word lines during the write operation.

First, a method for applying voltages to the word lines during the write operation when the central word line WLk (k is an integer greater than 6) in the NAND string is used as a selected word line is explained with reference to FIGS. 13 and 14.

In this case, if memory cell MCk1 is a selected memory cell and memory cell MCk2 is a write inhibition memory cell, the operation performed until pass voltage Vpass is applied is the same as that of the second embodiment and therefore the explanation thereof is omitted. Further, when word line WLk for which k≦6 is selected, the operation is the same as that of the second embodiment and therefore the explanation thereof is omitted.

When a preset period of time has elapsed after pass voltage Vpass was applied, pass voltage Vpass is applied to floating word lines WL(k−2) and WL(k−6). Then, after the channel voltage in the NAND string containing the write inhibition memory cell is sufficiently boosted, write voltage Vpgm (for example, 20 V) is applied to selected word line WLk.

As shown in FIG. 14, the boosting amount in intermediate voltage Vgp is reduced by applying pass voltage Vpass to the floating word line with a time delay in comparison with a case wherein pass voltage Vpass is applied to word lines WL(k−2) and WL(k−6) from the beginning.

Since the boosting amount of intermediate voltage Vgp is reduced, the boosting amount in cutoff voltage Viso is also reduced. As a result, the recovery time required for restoring original cutoff voltage Viso becomes shorter and the memory cell is cut off without fail. Thus, the time required for boosting the voltage of the channel region is reduced and the write time is reduced.

### (5) Third Embodiment

In the third embodiment, the intermediate voltage and cutoff voltage are not applied at the same time as application of the pass voltage and are applied with a preset time delay after the pass voltage was applied.

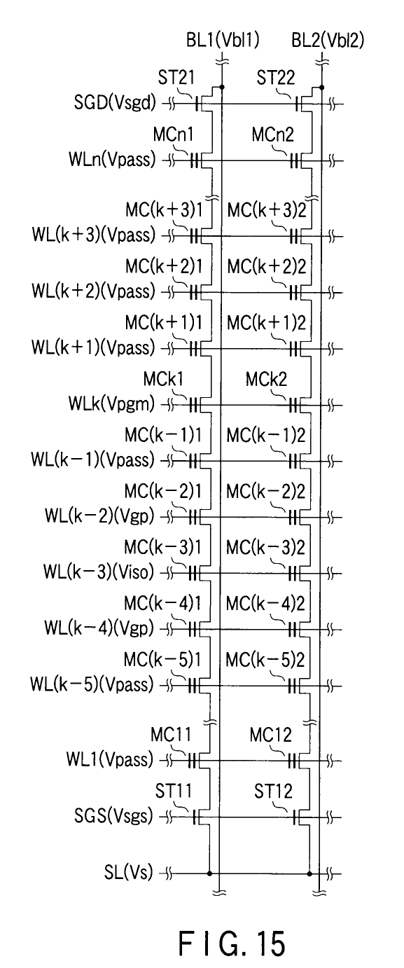

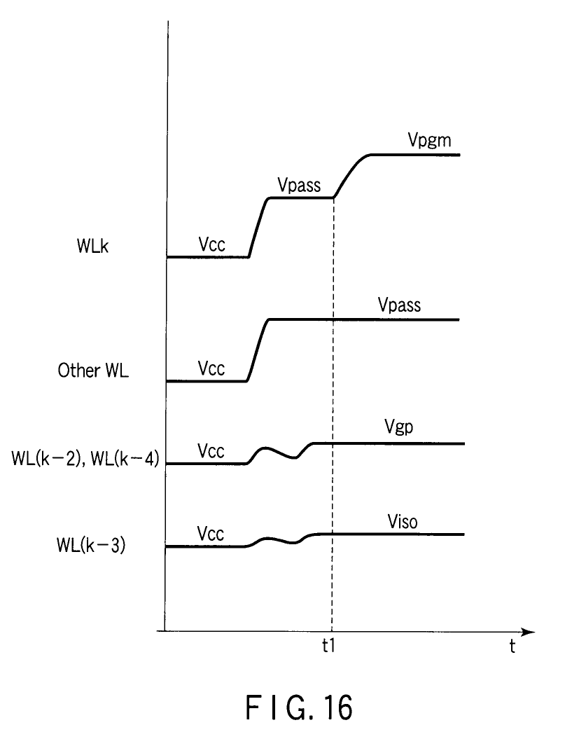

FIG. 15 shows the voltage relationship in the NAND cell unit during the write operation and FIG. 16 is a timing chart of voltages applied to word lines during the write operation.

First, a method for applying voltages to the word lines during the write operation when the central word line WLk (k is an integer greater than 4) in the NAND string is used as a selected word line is explained with reference to FIGS. 15 and 16. In this case, it is supposed that memory cell MCk1 is a selected memory cell and memory cell MCk2 is a write inhibition memory cell.

First, voltages Vb11, Vb12 are respectively applied to bit lines BL1, BL2. For example, it is supposed that voltage Vb11 is zero and voltage Vb12 is 2.5 V. Further, positive source voltage Vs (for example, a voltage of 2.5 V or less) is applied to the source line SL.

Voltage Vsgd (for example, a voltage of 2.5 V or less) is applied to selection gate line SGD of bit line selection gate transistors ST21, ST22. Voltage Vsgs (for example, 0 V) is applied to selection gate line SGS of source-side selection gate transistors ST11, ST12. Thus, selection gate transistors ST11, ST12 are cut off.

In the NAND cell unit including no selected memory cell, the channel region in the NAND string is charged to voltage Vcc (for example, approximately 0.5 V) via the selection gate transistor and is then made to float. In this case, Vcc is expressed by Vcc=Vb12−Vtsg and Vtsg is the threshold voltage of the selection gate transistor and is approximately 2.0 V, for example.

After this, pass voltage Vpass (for example, approximately 10 V) is applied to word lines other than word lines WL(k−2), WL(k−3) and WL(k−4). Then, cutoff voltage Viso (for example, approximately 1.0 V) is applied to word line WL(k−3) with a preset time delay after pass voltage Vpass was applied and intermediate voltage Vgp (for example, not lower than 1.0 V and lower than 10 V) is applied to word lines WL(k−2) and WL(k−4).

Subsequently, after the channel voltage in the NAND string containing the write inhibition memory cell is sufficiently boosted, write voltage Vpgm (for example, 20 V) is applied to selected word line WLk.

As shown in FIG. 16, the voltage applied to the word line is boosted because of coupling between the adjacent word lines when pass voltage Vpass is applied. Therefore, intermediate voltage Vgp applied to word lines WL(k−2) and WL(k−4) is boosted because of coupling with the pass voltage.

However, the boosting amount of intermediate voltage Vgp is reduced by applying intermediate voltage Vgp and cutoff voltage Viso with a delay with respect to timing at which pass voltage Vpass is applied in comparison with a case wherein intermediate voltage Vgp is applied from the beginning. Therefore, the boosting amount of cutoff voltage Viso applied to word line WL(k−3) is also reduced, the time required for recovery is reduced and the memory cell is cut off without fail.

In the example of FIG. 15, a case wherein the number of word lines to which pass voltage Vpass is applied and that are arranged between selected word line WLk and word line WL(k−2) to which intermediate voltage Vgp is applied is set to one is shown. However, this invention is not limited to this case and the number of word lines may be set to a plural number.

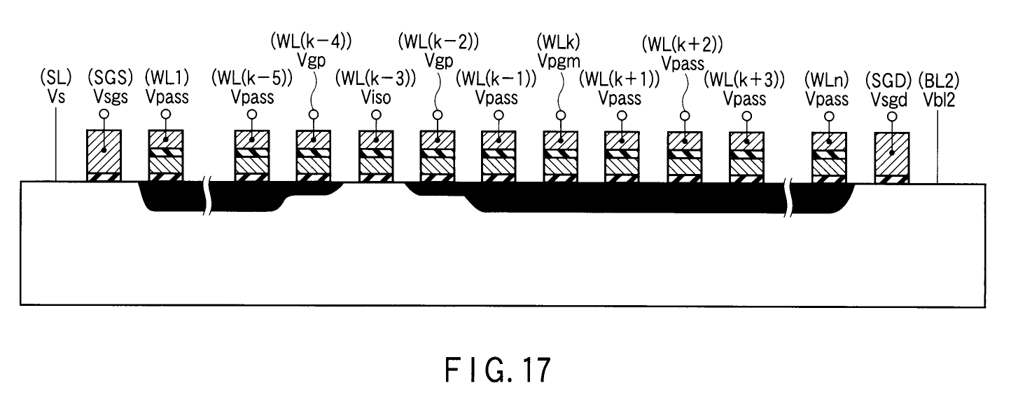

FIG. 17 is a cross-sectional view of the cell unit in the column direction. The depth of a region of the channel region painted in black indicates the magnitude of the channel voltage when pass voltage Vpass is applied to the word line.

Since the boosting amount in the intermediate voltage due to coupling with the pass voltage is reduced by applying the intermediate voltage and cutoff voltage with a time delay with respect to timing at which the pass voltage is applied, the boosting amount of the cutoff voltage is also reduced.

As a result, the recovery time required for restoring the original cutoff voltage is reduced and the channel of the memory cell can be cut off without fail. Therefore, the voltage of the channel region of the memory cell can be efficiently boosted. As a result, the timing at which write voltage Vpgm is applied to the selected memory cell can be made earlier and the time required for the write operation can be reduced.

Next, a case wherein the memory cell for which k≦4 is selected is explained. In the case of the selected memory cell for which k≦4, no memory cell to be cut off is present on the source line side of the selected memory cell in some cases. Therefore, the voltage of the channel region of the memory cell is boosted by use of the self-boost method.

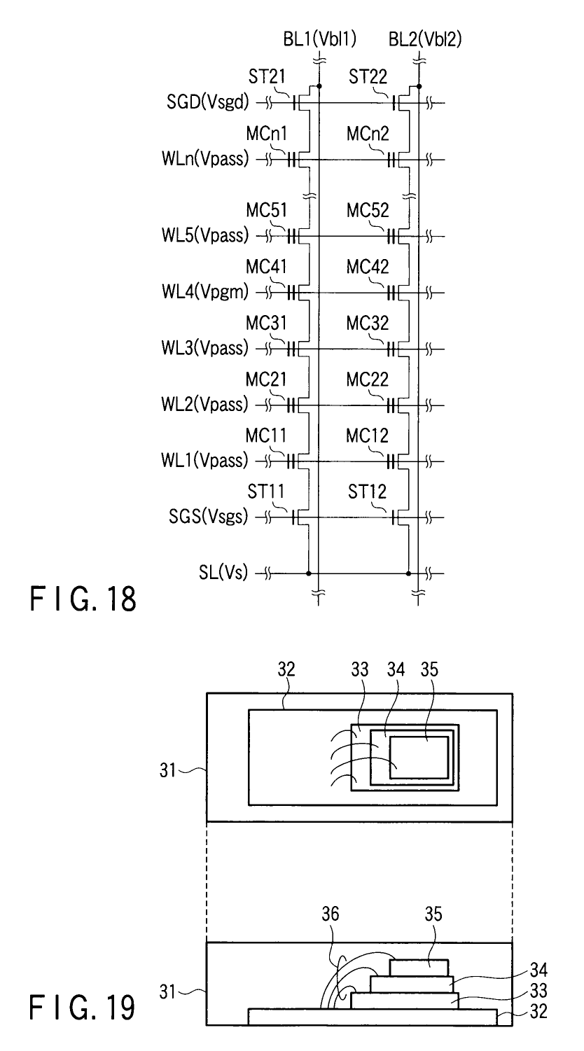

FIG. 18 shows a case wherein the memory cell for which k=4 is selected. First, as in the case in which the memory cell for which k≧5 is selected, the channel region of the NAND string including the write inhibition memory cell is made to float and pass voltage Vpass is applied to the respective word lines. The channel voltage in the NAND string is boosted because of capacitive coupling. Then, write voltage Vpgm is applied to selected word line WL4 and data is written.

In the above explanation, a case wherein the self-boost method is performed in the case of selected memory cell for which k≦4 is explained. However, if the memory cell for which k=4 is selected, the control operation may be performed to apply pass voltage Vpass to word lines other than word lines WL1 and WL2, apply the cutoff voltage to word line WL1 with a preset time delay after pass voltage Vpass was applied and apply intermediate voltage Vgp to word line WL2.

As described above in detail, in the third embodiment, in order to alleviate the influence caused by coupling with the pass voltage, the intermediate voltage and cutoff voltage are applied with a time delay after the pass voltage was applied. In this case, the amount of the intermediate voltage boosted by coupling with the pass voltage is reduced in comparison with a case wherein the intermediate voltage and cutoff voltage are applied from the beginning. Therefore, the boosting amount of the cutoff voltage is also reduced.

Therefore, the recovery time required for returning the boosted cutoff voltage of the word line to the original voltage becomes shorter and the memory cell is cut off without fail. Thus, the time required for boosting the voltage of the channel region is reduced and the write time is reduced.

Further, intermediate voltage Vgp lower than pass voltage Vpass is applied to the second memory cell adjacent to the first memory cell to which the cutoff voltage is applied. As a result, erroneous writing to the second memory cell can be prevented.

### 3. Application Example

In the above embodiments, it is supposed that the memory cell is formed with the stacked gate structure comprising the floating gate electrode and control gate electrode. However, the memory cell structure is not limited to this case. The above embodiments can also be applied to a memory cell with a metal oxide nitride oxide semiconductor (MONOS) structure using an insulating film such as a silicon nitride film as a charge storage layer.

An example of a system to which the NAND nonvolatile semiconductor memory of this invention is applied is explained.

FIG. 19 shows one example of a memory system.

The system is a memory card, universal serial bus (USB) memory or the like, for example.

In a package 31, a circuit board 32 and a plurality of semiconductor chips 33, 34 and 35 are arranged. The circuit board 32 and semiconductor chips 33, 34 and 35 are electrically connected via bonding wires 36. One of the semiconductor chips 33, 34 and 35 can be applied as the NAND nonvolatile semiconductor memory according to this invention.

### 4. Conclusion

According to this invention, the channel of the memory cell can be cut off without fail during the write operation.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A NAND nonvolatile semiconductor memory comprising:
a plurality of series-connected memory cells each comprising a charge storage layer and control gate electrode,
a plurality of word lines respectively connected to control gate electrodes of the memory cells,
a first selection transistor connected between one end of the memory cells and a source line,
a second selection transistor connected between the other end of the memory cells and a bit line, and
a driver configured to control voltages applied to the word lines,
wherein the driver applies a first voltage to a first word line connected to a selected memory cell, and applies a cutoff voltage that cuts off a channel of a memory cell to second word lines of a number not less than three arranged side by side on the source line side with respect to the first word line during a write operation.

2. The memory according to claim 1, wherein the driver applies a second voltage that is lower than the first voltage to a third word line adjacent to the second word lines on the bit line side.

3. The memory according to claim 2, wherein the driver applies the second voltage to a fourth word line adjacent to the second word lines on the source line side.

4. The memory according to claim 2, wherein the driver applies the first voltage to a fourth word line between the first and third word lines.

5. The memory according to claim 2, wherein the driver applies the first voltage to the word lines other than the first to third word lines.

6. The memory according to claim 1, wherein the driver applies a write voltage higher than the first voltage to the first word line after applying the first voltage to the first word line.

7. A NAND nonvolatile semiconductor memory comprising:
a plurality of series-connected memory cells each comprising a charge storage layer and control gate electrode,
a plurality of word lines respectively connected to control gate electrodes of the memory cells,
a first selection transistor connected between one end of the memory cells and a source line,
a second selection transistor connected between the other end of the memory cells and a bit line, and
a driver configured to control voltages applied to the plurality of word lines,
wherein the driver applies a first voltage to a first word line connected to a selected memory cell, makes a second word line arranged on the source line side of the first word line float, applies a second voltage lower than the first voltage to a third word line adjacent to the second word line on the source line side, and applies a cutoff voltage that cuts off a channel of a memory cell to a fourth word line adjacent to the third word line on the source line side during a write operation.

8. The memory according to claim 7, wherein the driver applies the first voltage to the second word line after making the second word float.

9. The memory according to claim 7, wherein the driver applies the second voltage to a fifth word line adjacent to the fourth word line on the source line side.

10. The memory according to claim 9, wherein the driver makes a sixth word line adjacent to the fifth word line on the source line side float.

11. The memory according to claim 7, wherein the driver applies the first voltage to a fifth word line between the first and second word lines.

12. The memory according to claim 7, wherein the driver applies the first voltage to the word lines other than the first to fourth word lines.

13. The memory according to claim 7, wherein the driver applies a write voltage higher than the first voltage to the first word line after applying the first voltage to the first word line.

14. A NAND nonvolatile semiconductor memory comprising:
a plurality of series-connected memory cells each comprising a charge storage layer and control gate electrode,
a plurality of word lines respectively connected to control gate electrodes of the memory cells,
a first selection transistor connected between one end of the memory cells and a source line,
a second selection transistor connected between the other end of the memory cells and a bit line, and
a driver configured to control voltages applied to the plurality of word lines,
wherein the driver applies a second voltage lower than a first voltage to a second word line arranged on the source line side of a first word line connected to a selected memory cell, and applies a cutoff voltage that cuts off a channel of a memory cell to a third word line adjacent to the second word line on the source line side after applying the first voltage to the first word line during a write operation.

15. The memory according to claim 14, wherein the driver applies the second voltage to a fourth word line adjacent to the third word line on the source line side.

16. The memory according to claim 14, wherein the driver applies the first voltage to a fourth word line between the first and second word lines.

17. The memory according to claim 14, wherein the driver applies the first voltage to the word lines other than the first to third word lines.

18. The memory according to claim 14, wherein the driver applies a write voltage higher than the first voltage to the first word line after applying the first voltage to the first word line.
